(19) United States
(12) Patent Application Publication
(10) Pub. No.: US 2010/0093548 A1
(43) Pub. Date: Apr. 15, 2010

(54) SUPERCONDUCTING STRUCTURE, APPARATUS FOR PROCESSING SUPERCONDUCTING STRUCTURE, AND METHOD FOR PROCESSING SUPERCONDUCTING STRUCTURE

(76) Inventor: Akira KAWAKAMI, Tokyo (JP)

Correspondence Address: BIRCH STEWART KOLASCH & BIRCH, PO BOX 747, FALLS CHURCH, VA, 22040-0747, US

(21) Appl. No.: 12/631,777

(22) Filed: Dec. 4, 2009

Related U.S. Application Data
(62) Division of application No. 11/217,358, filed on Sep. 2, 2005.

(51) Int. Cl. H01L 39/24

(52) U.S. Cl. 505/310; 505/410; 216/13

(57) ABSTRACT

A superconducting structure includes an NbN thin-film as a first superconducting thin-film layer on the upper surface of a substrate, an NbN thin-film as a second superconducting thin-film layer above the NbN thin-film, and a MgO thin-film as a protective thin-film provided between the NbN thin-film and the NbN thin-film.

The present application is a Divisional of co-pending U.S. patent application Ser. No. 11/217,358 filed Sep. 2, 2005, the entire contents of which are hereby incorporated by reference.

### BACKGROUND OF THE INVENTION

1. Field of the Invention

The present invention relates to a superconducting structure including a first superconducting thin-film layer on the upper surface of a substrate, a second superconducting thin-film layer above the first superconducting thin-film layer, and a protective thin-film layer between the first superconducting thin-film layer and the second superconducting thin-film layer; and to an apparatus thereof and method for processing the superconducting structure.

2. Description of the Related Art

In the fields of global environmental measurements and radio astronomy, the development of receivers and oscillators used in the terahertz (THz) frequency range has been desired.

An example of a superconducting structure used in such devices is a hot-electron bolometer (HEB). The hot-electron bolometer has been receiving attention as a low-noise mixer that overcomes problem the involving the superconducting gap frequency.

The hot-electron bolometer includes two electrodes composed of aluminum or the like and a superconducting thin-film strip composed of niobium nitride (NbN) or the like disposed between the electrodes, and the hot-electron bolometer is disposed center of thin-film metal antenna so that electromagnetic waves from the exterior is efficiently incident on the hot-electron bolometer. By taking advantage of the high nonlinearity of the resistance near the superconducting transition temperature of the thin-film NbN strip, heterodyne mixing is performed.

The performance of the hot-electron bolometer strongly depends on the characteristics of the superconducting ultra-thin-film. Thus, a technique for reducing the thickness of the film maintaining the good characteristics is important.

Examples of a method of etching such a thin-film include wet etching in which the film is dissolved in an acid or the like and dry etching in vacuo. The wet etching is rarely employed because of the difficulty of microfabrication and the fact that NbN is resistant to corrosion. Examples of dry etching include ion beam etching in which etching is physically performed by allowing accelerated particles to collide with the film and reactive ion etching in which etching is chemically performed with a reactive plasma gas. In both etching processes, a plasma gas is electrically accelerated to perform etching. However, the impact of the accelerated ions degrades the superconducting characteristics, such as the superconducting transition temperature Tc of the thin-film and resistivity thereof.

FIG. 14 is a graph illustrating the deterioration of the characteristics of an NbN thin-film due to the impact of accelerated argon (Ar) ions. Curve (A) shows the resistivity-temperature characteristics of an NbN thin-film 4 nm in thickness, curve (B) shows the resistivity-temperature characteristics of an NbN thin-film 3.2 nm in thickness prepared by irradiating an NbN thin-film 4 nm in thickness with an Ar ion beam accelerated by a voltage of 200 V, and curve (C) shows the resistivity-temperature curve of an NbN thin-film 3.2 nm in thickness prepared by irradiating an NbN thin-film 4 nm in thickness with an Ar ion beam accelerated by a voltage of 400 V. The three NbN thin-films each having a thickness of 4 nm are formed at the same time.

With respect to curves (B) and (C), since each 3.2-nm-thick film is thinner compared with the 4-nm-thick thin-film in curve (A), a decrease in transition temperature Tc and an increase in resistivity result inevitable. The Tc of the 3.2-nm-thick NbN thin-film is originally 8.5 K or more, and the characteristics deteriorate with an increase in ion beam voltage. Therefore, this shows that the impact of the ions impairs the superconducting characteristics. Furthermore, since the thin-film is exposed to charged particles during etching, a method for determining the thickness of the thin-film by measuring the resistance of the thin-film cannot be employed. Consequently, it is difficult to successfully reduce the thickness of the NbN thin-film from several tens of nanometers to several nanometers.

Reactive ion etching is a method including disposing a sample on a cathode of the etching system, introducing an etching gas, such as carbon tetrafluoride (CFO, into a chamber to an appropriate pressure, applying RF-power to the cathode to generate plasma, fluorinating (gasifying) a material etched with generated CF₃⁺ ions or fluoride radicals (F*), and evacuating the resulting fluoride.

In this method, the sample is directly exposed to plasma and is impacted by accelerated ions due to the cathode self-bias voltage V_{SELF}. Thus, the application of the method to the production of such an ultra-thin-film impairs the superconducting characteristics. In addition, it is difficult to reduce the thickness of the superconducting thin-film from several tens of nanometers to several nanometers because of a relatively high etching rate and the presence of “dead time” (time during which etching does not proceed) depending on the oxidation state of the surface.

The following Patent documents describing such techniques for processing thin-films are known.

Japanese Unexamined Patent Application Publication No. 2003-151964 discloses a process for producing a semiconductor device, the process including processing a silicon substrate by plasma etching.

The production process for a semiconductor device includes a step of etching the silicon substrate including an oxide film to reduce the thickness of the substrate. With respect to the conditions of the plasma etching applied in the step of reducing the thickness, the plasma discharge is performed under the conditions such that the product PL is in the range of 2.5 to 15 Pa·m, wherein P represents the pressure of a mixed gas fed into a chamber containing oxygen and a fluorine-based gas in discharging, and L represents the distance between electrodes.

Japanese Unexamined Patent Application Publication No. 1999-204846 discloses a process for producing a superconducting planar circuit, the process including adjusting the frequency characteristics of a high-temperature superconducting filter circuit to a target value.

The process includes the steps of forming a superconducting thin-film layer on a substrate, patterning the superconducting thin-film layer to form a planar circuit having predetermined circuit characteristics, and laminating an insulating thin-film layer having a predetermined thickness on the substrate having at least the planar circuit to change the predetermined circuit characteristics of the planar circuit.

Japanese Unexamined Patent Application Publication No. 1993-90501 discloses a process for producing, by, highly selective etching, a highly reliable film resistance that has no cavities at the ends of the thin-film resistance.

The process for producing a CrSi-based thin-film resistance on an oxide film includes the steps of generating plasma using a mixed gas containing CF₄ and oxygen, the oxygen content being 70 percent by volume or more, at a plasma-generating chamber in a plasma etching apparatus including the plasma-generating chamber and an etching chamber, the plasma-generating chamber and the etching chamber being separated, and selectively irradiating a CrSi-based film on the oxide film disposed in the etching chamber with the resulting activated fluoride radicals to etch the CrSi-based film on the oxide film with satisfactory selectivity.

### SUMMARY OF THE INVENTION

The above-described known art and other known art, however, do not include a thin-film-processing technique that can suppress a deterioration in the characteristics of the thin-film due to etching and that can stably control the thickness of the thin-film so that the thin-film has a target thickness of several nanometers.

To suppress a deterioration in the characteristics of a thin-film due to etching and to stably control the thickness of the thin-film so that the thin-film has a target thickness of several nanometers, the present invention provides a superconducting structure and a apparatus and a method for processing the superconducting structure.

According to an aspect of the present invention, a superconducting structure includes a substrate; a first superconducting thin-film layer on the upper surface of the substrate; a second superconducting thin-film layer above the first superconducting thin-film layer; and a protective thin-film provided between the first superconducting thin-film layer and the second superconducting thin-film layer.

According to the above-described aspect of the present invention, the protective thin-film may be composed of MgO.

According to the above-described aspect of the present invention, the protective thin-film may be formed by ion beam sputtering.

According to the above-described aspect of the present invention, the first superconducting thin-film layer may be composed of niobium nitride.

According to the above-described aspect of the present invention, the second superconducting thin-film layer may be composed of niobium nitride or titanium nitride.

According to the above-described aspect of the present invention, the first superconducting thin-film layer is formed by DC reactive sputtering.

According to another aspect of the present invention, a processing apparatus for etching a surface of a superconducting structure that includes a first superconducting thin-film layer on the upper surface of a substrate, a second superconducting thin-film layer above the first superconducting thin-film layer, and a MgO thin-film layer as a protective thin-film provided between the first superconducting thin-film layer and the second superconducting thin-film layer, the apparatus includes an ion source for generating fluoride radicals in an airtight chamber; and a shielding unit facing the ion source, the surface of the superconducting structure being etched by diffusing the fluoride radicals in the airtight chamber through a gap between the ion source and the shielding unit.

According to the above-described aspect of the present invention, the ion source is an electron cyclotron resonance ion source, and fluoride radicals are generated by introducing a CF₄ gas into the electron cyclotron resonance ion beam source.

According to another aspect of the present invention, a processing method for etching a surface of a superconducting structure with fluoride radicals, in which the superconducting structure includes a first superconducting thin-film layer on the upper surface of a substrate, a second superconducting thin-film layer above the first superconducting thin-film layer, and a MgO thin-film layer as a protective thin-film provided between the first superconducting thin-film layer and the second superconducting thin-film layer and is cut in a shape of rectangular (including a shape of square) and formed a monitor to measure resistance of film in the superconducting structure thereon, which method includes a cleaning step of cleaning the surface of the superconducting structure with an ion beam in advance; and a etching step of etching the second superconducting thin-film layer of the superconducting structure with the fluoride radicals.

According to the above-described aspect of the present invention, the etching step includes a monitoring step of monitoring the remaining thickness of a film in the superconducting structure based on film resistance thereof measured by the monitor to measure the resistance.

In the method for processing the superconducting structure by fluoride radical etching, it is considered that the fluoride radicals may be diffused depending on the concentration gradient from a radical source. Sample material can be etched by fluorination of the material with fluoride radicals, by gasification and removal of the fluoride by keeping a pressure in a reactor under vapor pressure of the fluoride. Fluoride radicals are electrically neutral, the etching rate of the material may simply depend on a solid angle of open space of the material to be etched. Therefore as shown FIG. 16, at a large solid angle (θ₂), the etching rate is high. At a small solid angle (θ₁), the etching rate is low. Positive use of this phenomenon permits control of the thickness based on the relationship between the etching time and the electrical resistance of the thin-film.

According to the present invention, in a superconducting structure including a first superconducting thin-film layer on the upper surface of a substrate, a second superconducting thin-film layer above the first superconducting thin-film layer, and a protective thin-film provided between the first superconducting thin-film layer and the second superconducting thin-film layer, the thickness and shape of the second superconducting thin-film layer can be controlled by etching the second superconducting thin-film layer by fluoride radical etching. Furthermore, by employing fluoride radical etching, a change in thickness during etching can be monitored by measuring the resistance. That is, by finishing etching at an appropriate film resistance, the thickness can be controlled more accurately.

Consequently, a superconducting structure having a suppressed deterioration in the characteristics of the thin-film and having a thin-film layer with a stably controlled target thickness of several nanometers can be provided.

The second superconducting thin-film layer may be composed of any material capable of being etched by fluoride radicals. Examples of the material include NbN, TiN, Nb, Ti, Mo, and Si. A device is produced with a superconducting thin-film with a thickness of several tens of nanometers. At the final stage, the film can be etched to a target thickness of several nanometers while suppressing electrical damage. Thus, the present invention is capable of adjusting impedance.

According to the present invention, a superconducting structure having no deterioration in the characteristics of the thin-film due to etching and having a thin-film layer with a stably controlled target thickness (film resistance) is produced, thus resulting in satisfactory reproducibility of the characteristics of the superconducting structure. Furthermore, the superconducting structure has high electrical strength and high mechanical strength due to a monolithic structure.

An inventive method for controlling the shape of a film etched by fluoride radical etching can be applied to control the thickness of the superconducting thin-film strip of HEBs, which are expected to be used as receivers in the terahertz frequency range in the fields of global environmental measurements and radio astronomy.

### BRIEF DESCRIPTION OF THE DRAWINGS

FIG. 1 is a cross-sectional view of a superconducting structure according to the present invention;

FIG. 2 is a schematic view illustrating a processing apparatus according to the present invention.

FIG. 3 is a graph showing the relationship between thin-film resistance and time.

FIG. 4 is a graph showing the thickness dependence of the resistivity and superconducting transition temperature of an NbN thin-film at a temperature of 20 K.

FIG. 5 is a schematic view of a resistance measuring monitor of superconducting structure.

FIG. 6 is a graph showing the actually measured relationship between thin-film resistance and etching time by a resistance measuring monitor of a film thickness.

FIGS. 7A to 7C are schematic cross-sectional views showing etched film.

FIGS. 8A to 8C show the principle of operation of an HEB heterodyne mixer.

FIG. 9A is a graph showing the calculated values of the etching time-resistance characteristics of the pattern for monitoring a film thickness in the HEB heterodyne mixer that has a strip length of 6 μm and a width of 40 μm; FIG. 9B is a schematic cross-sectional view of the HEB heterodyne mixer; FIG. 9C is a graph showing calculated values of the shape of the cross-section of the NbN strip when fluoride radical etching is stopped at the etching time “A-sim” in FIG. 9A; FIG. 9D is a graph showing calculated values of the shape of the cross-section of the NbN strip when fluoride radical etching is stopped at the etching time “B-sim” in FIG. 9A.

FIG. 10 is a micrograph of an NbN-HEB.

FIG. 11A is a graph showing the resistance-time characteristics of the NbN thin-film of Sample A; FIG. 11B is a cross-sectional transmission electron microscope image of an HEB; FIG. 11C is a graph showing the shape of the cross-section of the NbN strip obtained from a computer simulation.

FIG. 12A is a graph showing the resistance-time characteristics of the NbN thin-film of Sample B; FIG. 12B is a cross-sectional transmission electron microscope image of an HEB; FIG. 12C is a graph showing the shape of the cross-section of the NbN strip obtained from a computer simulation.

FIG. 13A is a schematic cross-sectional view of a known hot-electron bolometer; FIG. 13B is a schematic cross-sectional view of a hot-electron bolometer produced using a superconducting structure according to the present invention.

FIG. 14 is a graph showing a deterioration in the characteristics of NbN thin-films due to the impact of accelerated Ar ions.

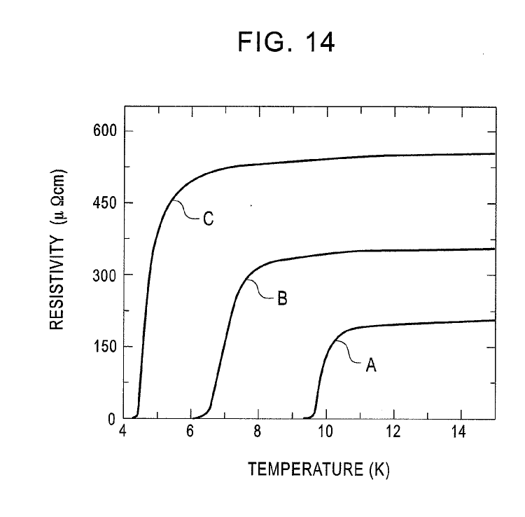

FIG. 15 shows an HEB heterodyne mixer.

FIG. 16 shows explanation of a large solid angle (θ₂) and small solid angle (θ₁).

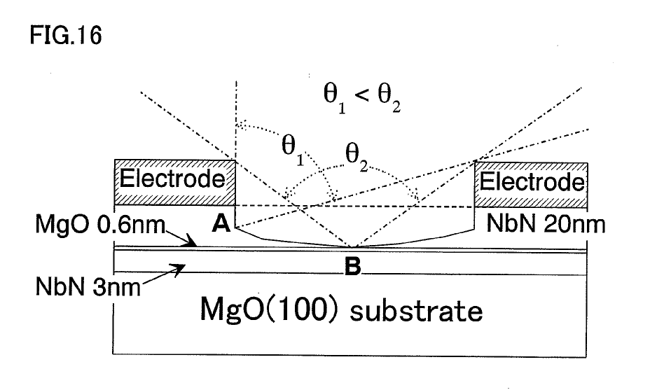

### DESCRIPTION OF THE PREFERRED EMBODIMENTS

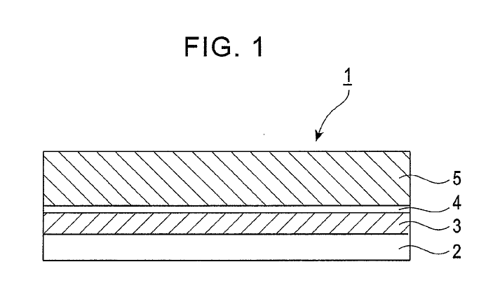

A superconducting structure 1 according to the present invention, shown in FIG. 1, is produced as follows. A single-crystal MgO substrate is used as a substrate 2. An NbN thin-film 3 having a thickness of 3 nm is formed as a first superconducting thin-film layer on the surface (100) of MgO substrate 2 by DC reactive sputtering with an Nb target. A MgO thin-film 4 having a thickness of 0.6 nm is formed as a protective thin-film on the NbN thin-film 3 by ion beam sputtering. Then, an NbN thin-film 5 having a thickness of 20 nm is formed as a second superconducting thin-film layer whose thickness will be controlled. Furthermore, an electrode pattern is formed on the NbN thin-film 5. In this way, for example, a circuit having an NbN/MgO/NbN/electrode structure is produced. In the superconducting structure 1, the thin-films are heteroepitaxially grown on the substrate 2, thus resulting in high bonding strength between the thin-films.

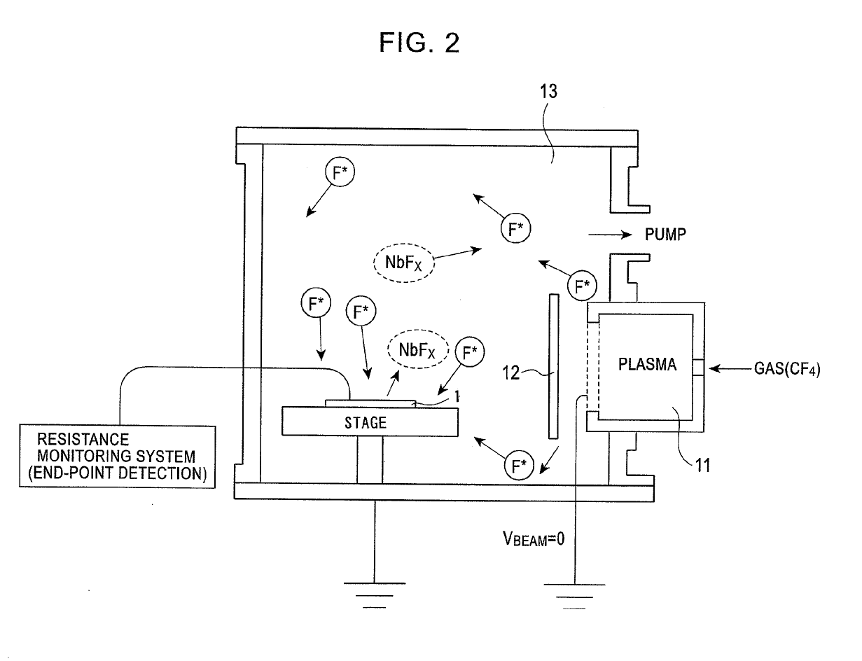

FIG. 2 is a schematic view showing an etching system according to the present invention. In the present invention, etching is performed using electroneutral fluoride radicals instead of electrically accelerated ions, thereby suppressing deterioration in the characteristics of the ultra-thin-film due to the impact of the ions. Furthermore, it is possible to monitor the film resistance of the device during etching.

In this embodiment, an electron cyclotron resonance (ECR) ion source is used as an ion source 11 generating fluoride radicals. Carbon tetrafluoride (CF₄) is used as a gas for generating the fluoride radicals. The CF₄ gas is introduced into the ion source 11. To satisfy the ECR conditions, a magnetic field and a microwave having a frequency of 2.45 GHz are applied to generate plasma. In typical ion beam etching, a DC voltage is applied to an ion extraction grid to accelerate CF₃⁺ ions, and a superconducting structure disposed at a position such that an incidence angle is an appropriate value is irradiated with the ions. However, in the inventive process of performing etching using fluoride radicals, no voltage is applied to the ion extraction grid, and a shutter (shielding unit) 12 disposed in front of the ion source 11 is closed so that the radicals do not directly reach from the ion source 11 to the sample. Furthermore, the sample is disposed at a position such that the incidence angle is 0°.

The generated fluoride radicals diffuse depending on the concentration gradient from a few centimeters gap between the ion source 11 and the shutter 12. Only fluoride radicals that reach the superconducting structure 1 functions as an etchant for etching the NbN thin-film.

To measure the thickness of a thin-film layer in the superconducting structure, a monitor to measure the film resistance of the superconducting structure 1 (hereinafter it referrers “resistance measuring monitor”) is formed on the surface of the superconducting structure 1 in advance. By measuring the resistance of the superconducting structure 1 during the etching step, remaining thickness of a thin-film layer in the superconducting structure, that is, condition of etching thereof can be predicted. In the present invention, the resistance of the superconducting structure 1 can be measured during etching because electroneutral fluoride radicals are used for etching. Incidentally, a resistance measuring monitor will hereinafter be described in detail.

Next, in a cleaning step, the surface of the NbN thin-film 5 is cleaned with Ar ion beam or the like to remove an oxide film and the like. Then, in an etching step, the surface of the NbN thin-film 5 is etched by radical etching. The NbN thin-film 5 having an initial thickness of about several tens of nanometers can protect the NbN thin-film 3 from damage due to cleaning with the ion beam.

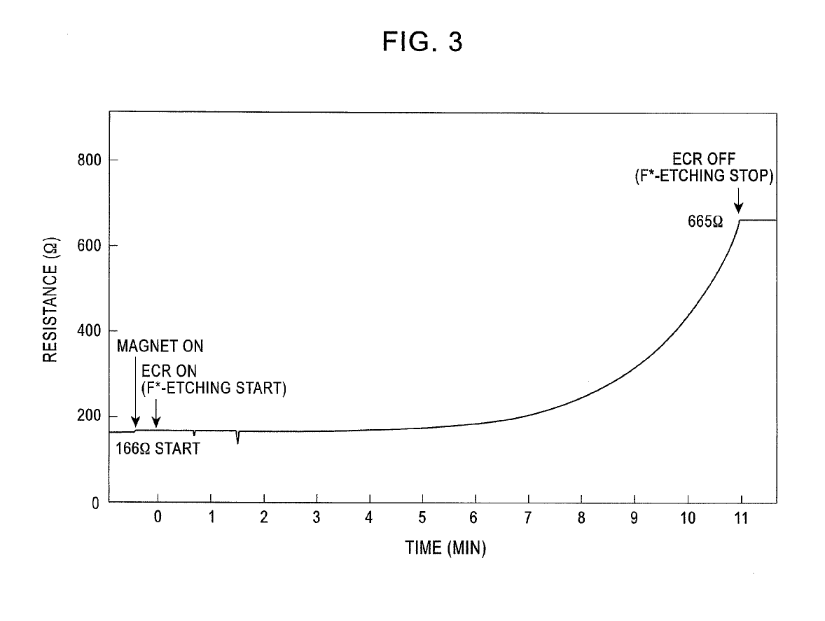

FIG. 3 shows a graph of the relationship between thin-film resistance of NbN monolayer and time. In general, thin-film resistance is inversely proportional to thickness if resistivity does not depend on film thickness. In this embodiment, a thin-film 20 nm in thickness had an initial film resistance of 166Ω before fluorine-radical etching. The resistance of the thin-film was increased to 665Ω 11 minutes after etching. Incidentally, the resistance measurement was little affected by etching.

It is estimated that the thickness of the NbN monolayer is 4.8 nm from the final resistance when resistivity is constant. The thickness is measured with a stylus-based surface profiler (Alpha-Step 500, vertical resolution: 0.1 nm, manufactured by KLA-Tencor Corporation). The result showed that the thickness was 5.4 nm. Since thickness of the NbN monolayer is hypothesized as constant in the above calculation and resistivity in the initial stage of the deposition of the film becomes to increase, the actual measurement value of 5.4 is considered to be reasonable.

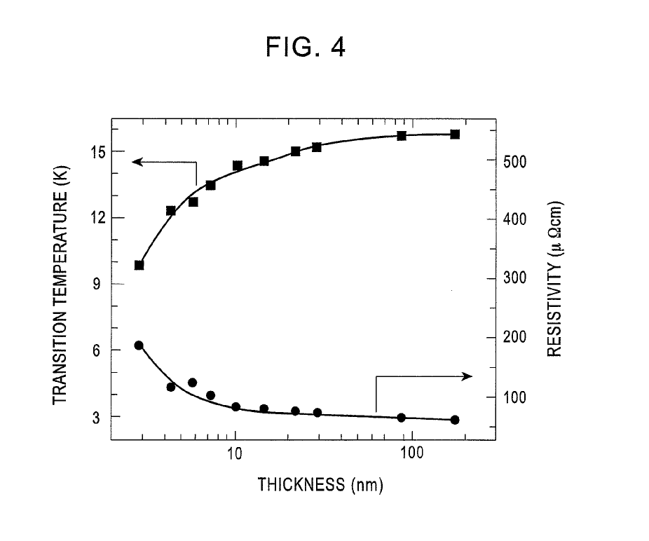

FIG. 4 is a graph showing the thickness dependence of the resistivity and superconducting transition temperature of an NbN thin-film at a temperature of 20 K. The superconducting transition temperature Tc of NbN film 5 in thickness of 5.4 nm is 12.7K and resistivity (ρ) is 110 μΩcm in FIG. 4. After fluoride radical etching, the superconducting transition temperature Tc and the resistivity ρ_{20K} at a temperature of 20 K of the NbN monolayer were 11.3 K and 92 μΩcm, respectively. The results showed no damage due to etching because Tc of NbN monolayer is lower but resistivity is lower and the property is superior.

If temperature dependence of the resistivity of the material at from room temperature to near superconducting transition temperature is known when superconducting material such as NbN film is used, the actual resistance of the device can be easily predicted by setting an appropriate resistance of the device at room temperature. As a result, the reproducibility of the characteristics of devices, such as a hot-electron bolometer including NbN, is improved by the reason.

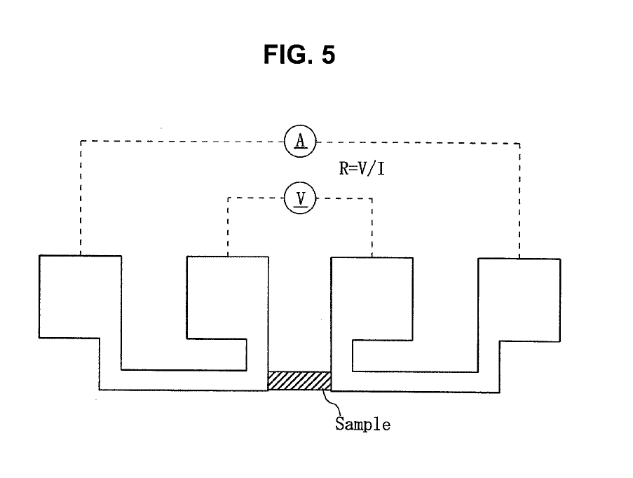

As an example of processing method for an HEB mixer, it is described in advance a resistance measuring monitor formed on the surface of superconducting structure by ion beam prior to cleaning step. FIG. 5 shows a method for evaluation of film resistance of the superconducting structure by four-end terminal method. Firstly, the superconducting structure is cut in a shape of rectangular, then four electrodes made of Al thin-film are prepared on the surface of the superconducting structure by photolithography. Since the thickness to be etched of the superconducting structure is known, in view of film resistance value of the thin-film measured by four-end terminal method, thickness of the superconducting can be predicted during etching step.

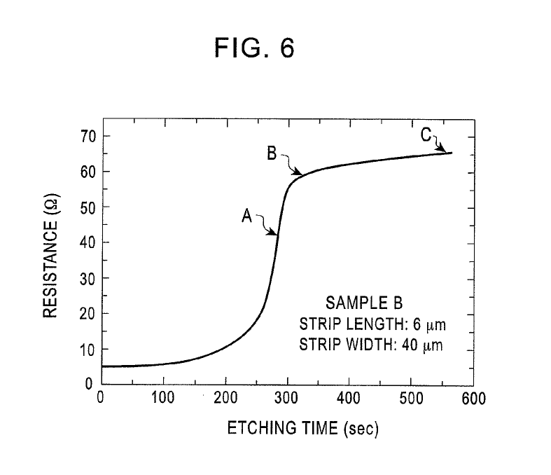

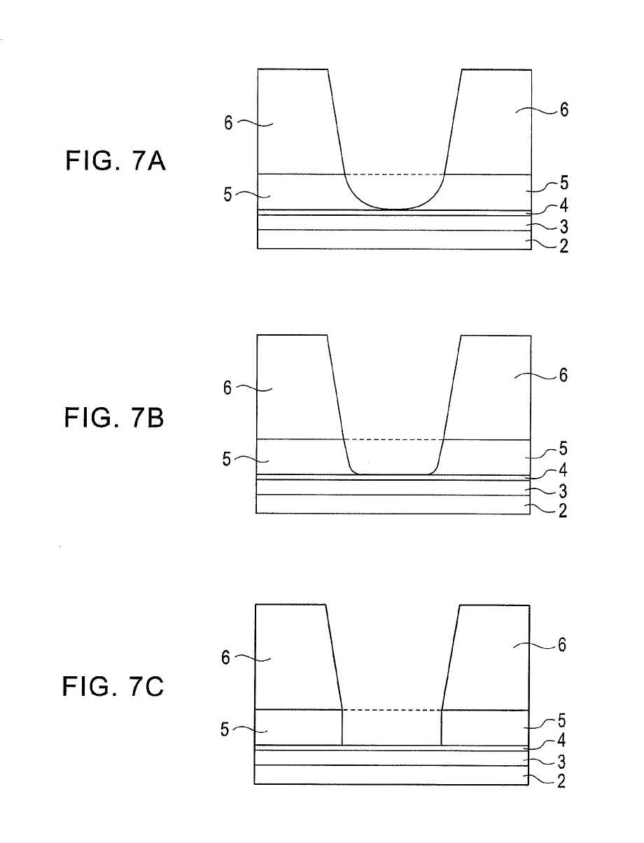

FIG. 6 is a graph showing the actually measured relationship between thin-film resistance and etching time of the superconducting structure. FIGS. 7A to 7C are schematic cross-sectional views showing etched film. At point A shown in FIG. 6, the maximum change in film resistance due to etching is observed. This is because the NbN thin-film 5 at the middle portion of the NbN strip between electrodes 6 is etched by etching to expose the MgO thin-film 4 (FIG. 7A). At point B shown in FIG. 6, substantially the entire NbN thin-film 5 in the NbN strip between electrodes 6 is etched to expose the MgO thin-film 4. At this point, etching is substantially completed (FIG. 7B). The etching rate near the electrodes is decreased to at most about half that at the middle portion of the NbN strip between the electrodes. At point C shown in FIG. 6, since the etching time at point C is twice as long as that at point A, even the NbN thin-film 5 near the electrodes is etched by etching to expose the MgO thin-film 4 (FIG. 7C). Thus, by using a film resistance of superconducting structure measured as an indicator, it is known etching condition of superconducting structure during etching step.

Note that the MgO thin-film 4 having a thickness of 0.6 nm functions as an etching stopper. Therefore, even when the entire NbN thin-film 5 between the electrodes is completely etched, the NbN thin-film 3 is not etched and is maintained at a thickness of 3 nm. In this way, since a change in thickness can be monitored by measuring the resistance of superconducting structure during fluoride radical etching, it is possible to accurately design the thickness of the NbN thin-film 5 by controlling etching time. Additionally, since the MgO thin-film 4 is very thin, the superconducting tunneling current density is 20 kA/cm², the NbN thin-films 3 and 5 are regarded as a single superconductor. A hot-electron bolometer is thereby produced.

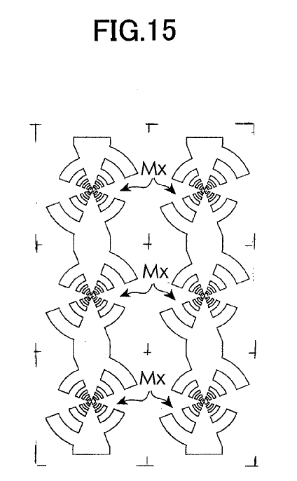

The present invention has essential feature that by using a superconducting structure comprising a substrate, a first superconducting thin-film layer on the upper surface of the substrate, a second superconducting thin-film layer above the first superconducting thin-film layer, and a protective thin-film provided between the first superconducting thin-film layer and the second superconducting thin-film layer, the remaining thickness of the superconducting structure is monitored based on the resistance values of the superconducting structure measured by a resistance measuring monitor formed on the surface of the structure. FIG. 15 shows an HEB mixer prepared according to the above description, in which six HEB mixer Mxs having quasi-planar antenna are shown.

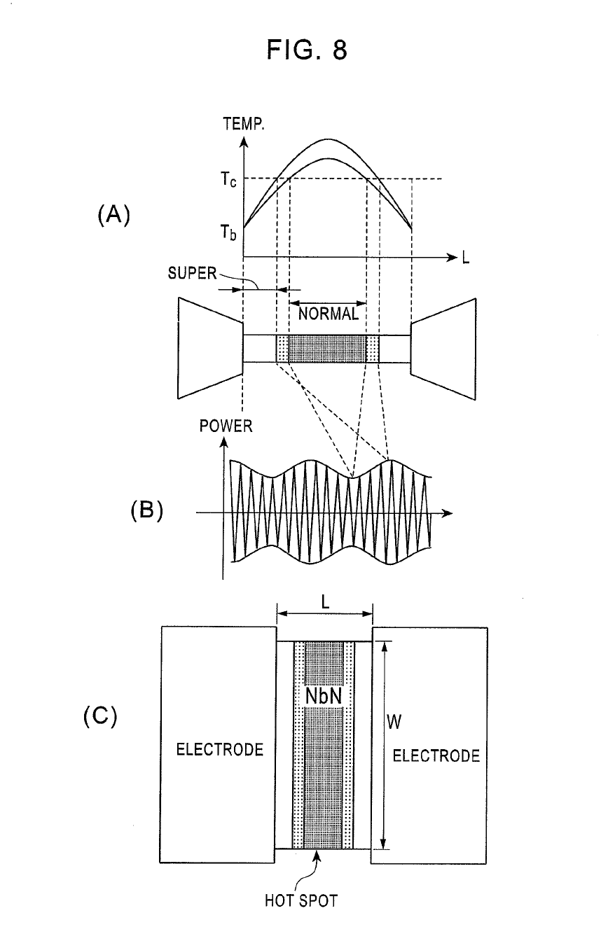

FIGS. 8A to 8C show the principle of operation of an HEB heterodyne mixer. When the HEB functions as a heterodyne receiver for receiving electromagnetic waves, a signal source and a local oscillation source are incident on the HEB. First, a region what is called “hot spot”, which is a normal state, is generated at the middle portion of the superconducting strip between the electrodes by appropriately applying an incident power of the local oscillation source and a DC bias power (FIG. 8 (A)). Next, a weak signal source power is applied to the hot spot, and then this region is increased or decreased depending on the signal source power (FIG. 8 (B)), thus resulting in a change in the resistance of the HEB. This change in film resistance is converted into a voltage or a current by applying an appropriate DC bias to obtain an intermediate frequency output (IF output).

The hot spot is generated at the middle portion of the superconducting strip on the grounds of high heat-releasing efficiency based on high thermal conductivity of the electrodes each composed of an electrically low-loss material. In general, to match the impedance of the HEB to that of the antenna, the width W (up to about 2.5 μm) of the superconducting strip is greater than the length L (0.5 μm or less) of the superconducting strip. One of the problems of the HEB relates to an increase in IF bandwidth. The IF bandwidth can be increased by reductions in the length and thickness of the strip, i.e., miniaturization. This leads to a longitudinal shape of the hot spot. In a uniform-thick NbN strip, it is estimated that the hot spot is difficult to be successfully generated at the middle portion of the NbN strip between the electrodes (FIG. 8 (C)), thus leading to instability of the IF output.

To successfully generate the hot spot and achieve a reliable IF output, the thickness distribution of the superconducting strip is slightly changed, i.e., the thickness of the NbN strip near the electrodes is increased and the thickness at the middle portion of the NbN strip between the electrodes is decreased, so that the lowermost superconducting transition temperature is achieved at the middle portion of the NbN strip between the electrodes.

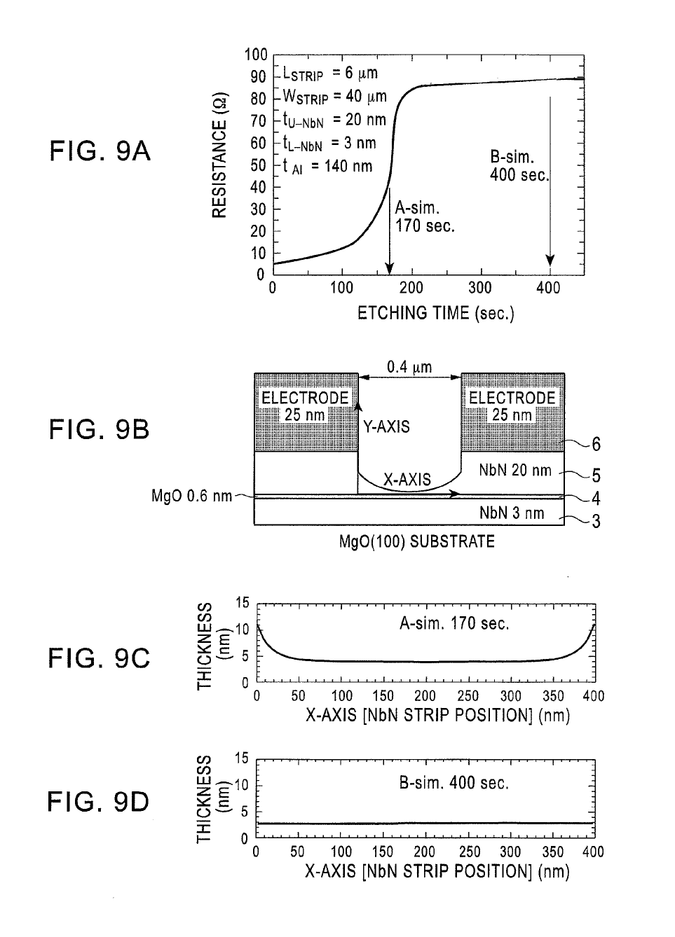

FIGS. 9A to 9D show the dependence of the etching rate on a solid angle at a position to be etched simulated by a computer simulation. FIG. 9A is a graph showing the calculated value of the etching time-resistance characteristics of the monitor for a film thickness in the HEB heterodyne mixer that has a strip length of 6 μm and a width of 40 μm. FIG. 9B is a schematic cross-sectional view of the HEB heterodyne mixer during etching. FIG. 9C is a graph showing calculated values of the shape of the cross-section of the NbN strip when fluoride radical etching is stopped at the etching time “A-sim” in FIG. 9A. FIG. 9D is a graph showing calculated values of the shape of the cross-section of the NbN strip when fluoride radical etching is stopped at the etching time “B-sim” in FIG. 9A.

FIG. 9D shows that the entire NbN thin-film 5 is completely etched by etching to expose the MgO thin-film 4 and that the thickness is constant, i.e., 3 nm, which is the thickness of the NbN thin-film 3. On the other hand, FIG. 9C shows that the thickness of the NbN thin-film 5 near the electrodes 6 is larger than other portions of the NbN thin-film 5 between the electrodes. This results in a difference between the superconducting transition temperature of the NbN strip at the vicinities of the electrodes 6 and that at the middle portion of the NbN strip.

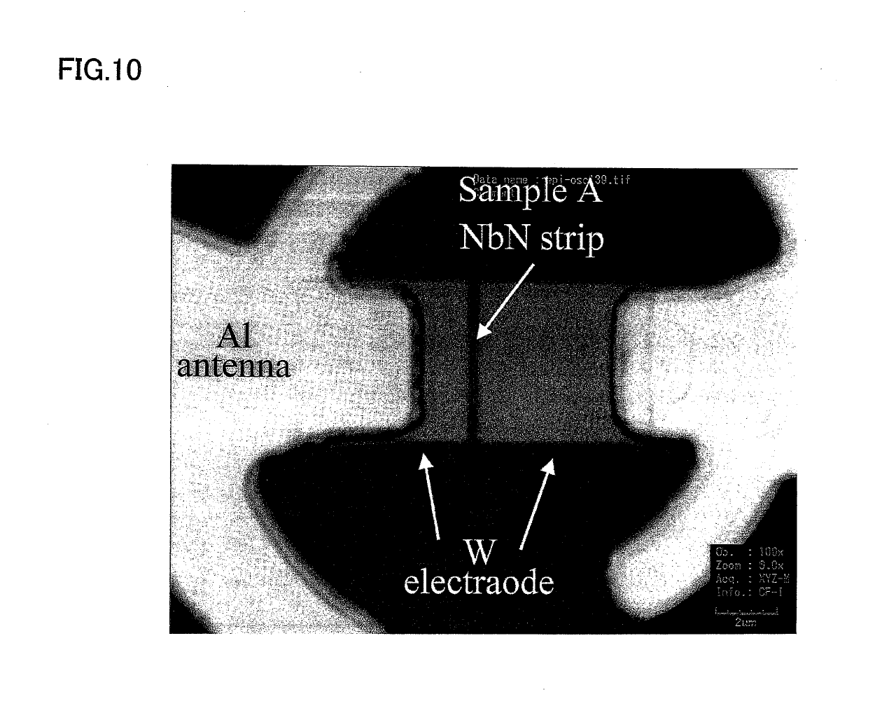

FIG. 10 is a micrograph of an HEB device actually produced by the inventive method for controlling the shape of a film etched by fluoride radical etching. The thicknesses of the NbN thin-film 3, the NbN thin-film 5, and the tungsten (w) electrode 6 are 3 nm, 20 nm, and 25 nm, respectively. The NbN strip has a length of 0.4 μm and a width of 2.5 μm.

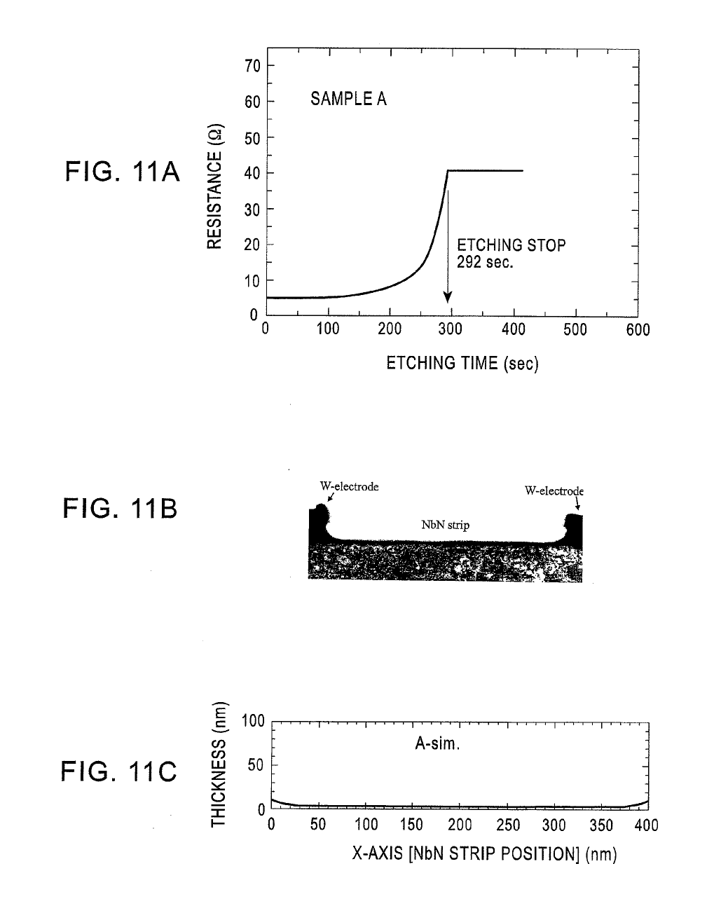

As shown in FIGS. 11A to 11C, in sample A corresponding to A-sim shown in FIG. 9A, the NbN strip is inclined near the electrodes. FIG. 11A is a graph showing the resistance-time characteristics of the NbN thin-film. FIG. 11B is a cross-sectional transmission electron microscope image of an NbN thin-film. FIG. 11C is a graph showing the shape of the cross-section of the NbN strip obtained from a computer simulation.

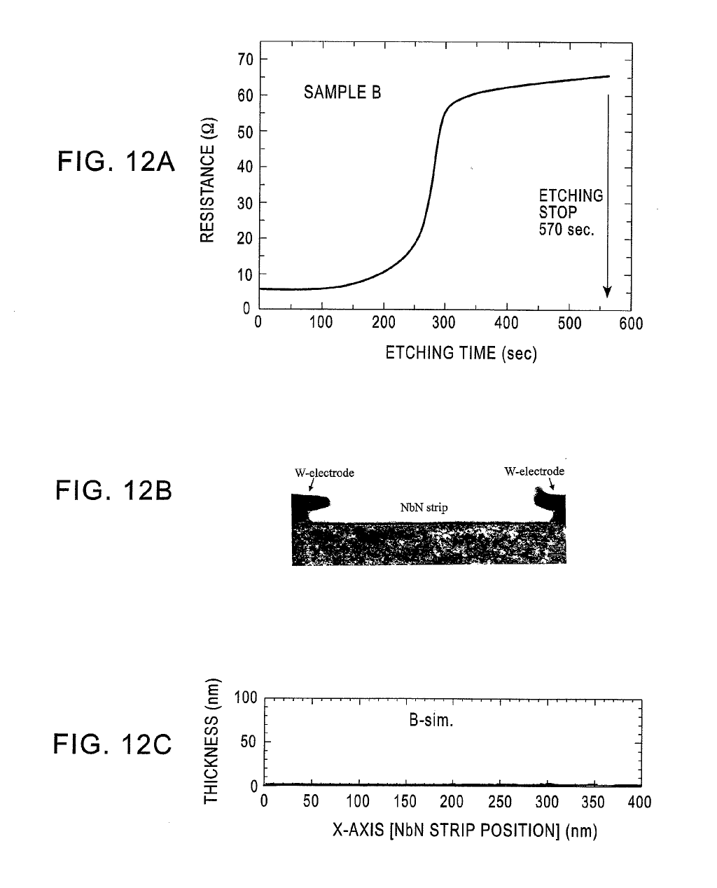

As shown in FIGS. 12A to 12C, in sample B corresponding to B-sim shown in FIG. 9A, the NbN strip is flat and is maintained at a thickness of about 3 nm by providing the MgO thin-film functioning as an etching stopper, which are in accordance with the result of calculations. FIG. 12A is a graph showing the resistance-time characteristics of the NbN thin-film. FIG. 12B is a cross-sectional transmission electron microscope image. FIG. 12C is a graph showing the shape of the cross-section of the NbN thin-film obtained from a computer simulation. The results described above shows that, by employing fluoride radical etching of the present invention, the shape of the strip of the HEB can be controlled.

The HEB has been receiving attention as a low-noise mixer.

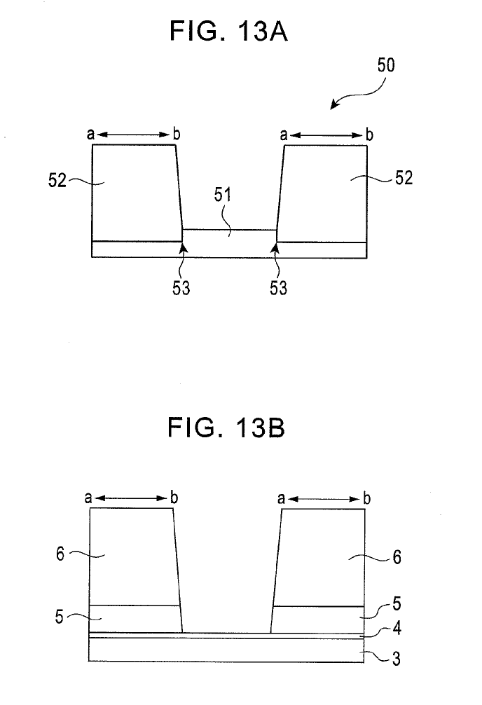

We also have studied the HEB. The HEB disadvantageously has low mechanical and electrical properties. FIG. 13A is a schematic view of an HEB produced by a known production process. In the known production process, metal electrodes 52 are formed on a (superconducting) NbN thin-film 51 having a thickness of about 3 nm to produce HEB 50. Ar ion beam cleaning that is performed before forming the metal electrodes 52 composed of aluminum or the like reduces the thickness of the NbN thin-film 51, thus increasing the possibility of a break due to surges from the exterior (a reduction in electrical strength). Furthermore, the superconducting characteristics of the NbN thin-film under the metal electrodes 52 are impaired.

The HEB is required to be cooled to about the liquid helium temperature (4.2 K) because the HEB uses a steep change in resistance-temperature characteristics at about the superconducting transition temperature. Therefore, the stress in the a-b directions of the metal electrodes 52 is increased, thus causing the break of the NbN thin-film 51 at edges 53.

To solve the problems, the inventive device structure shown in FIG. 13B is applicable. As described above, the HEB device structure is produced as follows: The MgO thin-film 4 having a thickness of 0.6 nm and the NbN thin-film 5 having a thickness of 20 nm are formed in that order on the NbN thin-film 3 having a thickness of 3 nm. Then, the electrodes 6 are deposited, and the NbN thin-film 5 is etched until the thickness reaches about 3 nm.

Here, as described above, the interlayer MgO thin-film functioning as an etching stopper has a very small thickness of 0.6 nm and has low tunnel resistance, thus being electrically negligible. The NbN thin-film 3 is maintained at a thickness of 3 nm by providing the MgO thin-film 4, thus increasing mechanical and electrical strength. Furthermore, a deterioration in superconducting characteristics due to Ar ion cleaning can be prevented by providing the NbN thin-film 5 having an initial thickness of about several tens of nanometers.

As described in detail above, the superconducting structure 1 includes the NbN thin-film (first superconducting thin-film layer) 3 on the upper surface of the substrate 2, the NbN thin-film (second superconducting thin-film layer) 5 above the NbN thin-film 3, and the MgO thin-film (protective thin-film) 4 provided between the NbN thin-film 3 and the NbN thin-film 5. The MgO thin-film (protective thin-film) 4 may be formed by ion beam sputtering. The second superconducting thin-film layer may be a titanium nitride film instead of the NbN thin-film 5. The NbN thin-film 3 may be formed by DC reactive sputtering.

The processing apparatus for etching a surface of the superconducting structure 1 that comprises the NbN thin-film (first superconducting thin-film layer) 3 on the upper surface of the substrate 2, the NbN thin-film (second superconducting thin-film layer) 5 above the NbN thin-film 3, and the MgO thin-film (protective thin-film) 4 provided between the NbN thin-film 3 and the NbN thin-film 5, the apparatus includes the ion source 11 for generating fluoride radicals in the airtight chamber 13; and the shutter (shielding unit) 12 facing the ion source 11, the surface of the superconducting structure 1 being etched by diffusing the fluoride radicals in the airtight chamber 13 through a gap between the ion source 11 and the shutter 12. The ion source 11 may be an electron cyclotron resonance ion beam source, and fluoride radicals may be generated by introducing a CF₄ gas into the electron cyclotron resonance ion beam source. Furthermore, etching may be performed in the airtight chamber 13 at reduced pressure.

The processing method for etching a surface of the superconducting structure 1 with fluoride radicals, the superconducting structure including the NbN thin-film (first superconducting thin-film layer) 3 on the upper surface of the substrate 2, the NbN thin-film (second superconducting thin-film layer) 5 above the NbN thin-film 3, and the MgO thin-film (protective thin-film) 4 provided between the NbN thin-film 3 and the NbN thin-film 5, being cut in a shape of rectangular and formed a resistance measuring monitor on the surface of the superconducting structure, which method includes the cleaning step of cleaning the surface of the superconducting structure 1 with an ion beam in advance; and the etching step of etching the NbN thin-film 5 of the superconducting structure in the superconducting structure 1 with the fluoride radicals. The etching step may include the monitoring step of monitoring the remaining thickness of the NbN thin-film 5 in the superconducting structure 1 measured through a resistance measuring monitor prepared on the surface of the superconducting structure.

What is claimed is:

1. A processing method for etching a surface of a superconducting structure with fluoride radicals, in which the superconducting structure comprises a first superconducting thin-film layer on the upper surface of a substrate, a second superconducting thin-film layer above the first superconducting thin-film layer, and a MgO thin-film layer provided between the first superconducting thin-film layer and the second superconducting thin-film layer and is cut in a shape of rectangular and formed a monitor to measure resistance of film in the superconducting structure thereon,
which process comprises
a cleaning step of cleaning the surface of the superconducting structure with an ion beam in advance; and
a etching step of etching the second superconducting thin-film layer of the superconducting structure with the fluoride radicals.

2. The processing method according to claim 1, which further comprises
a monitoring step of monitoring the remaining thickness of a film in the superconducting structure based on film resistance thereof measured by the monitor to measure the resistance.
